(19) United States
(12) Patent Application Publication
(10) Pub. No.: US 2026/0023139 A1
(43) Pub. Date: Jan. 22, 2026

(54) MAGNETORESISTIVE RANDOM-ACCESS MEMORY DEVICE WITH ENCASED FREE LAYER

(71) Applicant: International Business Machines Corporation, Armonk, NY (US)

(72) Inventors: Oscar van der Straten, Guilderland Center, NY (US); Gabriel Rodriguez, Albany, NY (US); Chih-Chao Yang, Glenmont, NY (US)

(21) Appl. No.: 18/780,271

(22) Filed: Jul. 22, 2024

(51) Int. Cl. G01R 33/09; H10B 61/00; H10N 50/01; H10N 50/10; H10N 50/20

(52) U.S. Cl. CPC G01R 33/098; H10B 61/10; H10N 50/01; H10N 50/10; H10N 50/20

(57) ABSTRACT

A magnetic tunnel junction device and formation thereof. The magnetic tunnel junction device includes a magnetic tunnel junction pillar formed above a bottom electrode. The magnetic tunnel junction pillar includes a reference layer formed on top of the bottom electrode, a dielectric layer formed on top of the reference layer, a free layer formed within the dielectric layer and partially within a recessed area of the reference layer, and a tunnel barrier layer separating the reference layer from the free layer, where the tunnel barrier layer covers bottom and sidewall surfaces of the free layer. The magnetic tunnel junction pillar device further includes a top electrode formed above the magnetic tunnel junction pillar.

### BACKGROUND

The present invention generally relates to fabrication methods and structures for magnetic tunnel junction (MTJ) devices, and more specifically, to fabrication methods and structures for MTJ devices having an encased free layer.

A magnetoresistive random-access memory (MRAM) device is a type of solid state, non-volatile memory which stores data in an electrically connected array of magnetoresistive memory elements, referred to as magnetic tunnel junctions (MTJs).

### SUMMARY

According to an embodiment of the present invention, a magnetic tunnel junction device is provided. The magnetic tunnel junction device includes a magnetic tunnel junction pillar formed above a bottom electrode. The magnetic tunnel junction pillar includes a reference layer formed on top of the bottom electrode, a dielectric layer formed on top of the reference layer, a free layer formed within the dielectric layer and partially within a recessed area of the reference layer, and a tunnel barrier layer separating the reference layer from the free layer, where the tunnel barrier layer covers bottom and sidewall surfaces of the free layer. The magnetic tunnel junction pillar device further includes a top electrode formed above the magnetic tunnel junction pillar.

According to another embodiment of the present invention, a method of forming a magnetic tunnel junction device is provided. The method includes forming a magnetic tunnel junction pillar above a bottom electrode. Forming the magnetic tunnel junction pillar includes: forming a reference layer on top of the bottom electrode, forming a dielectric layer above the reference layer, forming an opening that extends completely through the dielectric layer and partially through the reference layer, conformally depositing a tunnel barrier material to form a tunnel barrier layer on bottom and sidewall surfaces of the opening, such that the tunnel barrier layer lines the opening, and forming a free layer within the opening lined by the tunnel barrier layer. The method further includes forming a top electrode above the free layer.

### BRIEF DESCRIPTION OF THE SEVERAL VIEWS OF THE DRAWINGS

The drawings included in the present application are incorporated into, and form part of, the specification. They illustrate embodiments of the present invention and, along with the description, explain the principles of the invention. The drawings are only illustrative of certain embodiments and do not limit the invention.

FIG. 1 illustrates a cross-sectional view of a magnetic tunnel junction (MTJ) device 100 at an intermediate step during a semiconductor manufacturing process, in accordance with at least one embodiment of the present invention.

FIG. 2 illustrates a cross-sectional view of MTJ device 100 of FIG. 1 after performing subsequent processing steps, in accordance with at least one embodiment of the present invention.

FIG. 3 illustrates a cross-sectional view of MTJ device 100 of FIG. 2 after performing subsequent processing steps, in accordance with at least one embodiment of the present invention.

FIG. 4 illustrates a cross-sectional view of MTJ device 100 of FIG. 3 after performing subsequent processing steps, in accordance with at least one embodiment of the present invention.

FIG. 5 illustrates a cross-sectional view of MTJ device 100 of FIG. 4 after performing subsequent processing steps, in accordance with at least one embodiment of the present invention.

FIG. 6 illustrates a cross-sectional view of MTJ device 100 of FIG. 5 after performing subsequent processing steps, in accordance with at least one embodiment of the present invention.

FIG. 7 illustrates a cross-sectional view of MTJ device 100 of FIG. 6 after performing subsequent processing steps, in accordance with at least one embodiment of the present invention.

FIG. 8 illustrates a cross-sectional view of MTJ device 100 of FIG. 7 after performing subsequent processing steps, in accordance with at least one embodiment of the present invention.

FIG. 9 illustrates a cross-sectional view of MTJ device 100 of FIG. 8 after performing subsequent processing steps, in accordance with at least one embodiment of the present invention.

FIG. 10 illustrates a cross-sectional view of MTJ device 100 of FIG. 9 after performing subsequent processing steps, in accordance with at least one embodiment of the present invention.

FIG. 11 illustrates a cross-sectional view of MTJ device 100 of FIG. 10 after performing subsequent processing steps, in accordance with at least one embodiment of the present invention.

FIG. 12 illustrates a cross-sectional view of MTJ device 100 of FIG. 11 after performing subsequent processing steps, in accordance with at least one embodiment of the present invention.

FIG. 13 illustrates a cross-sectional view of MTJ device 100 of FIG. 12 after performing subsequent processing steps, in accordance with at least one embodiment of the present invention.

FIG. 14 illustrates a cross-sectional view of MTJ device 100 of FIG. 13 after performing subsequent processing steps, in accordance with at least one embodiment of the present invention.

FIG. 15 illustrates a cross-sectional view of MTJ device 100 of FIG. 14 after performing subsequent processing steps, in accordance with at least one embodiment of the present invention.

FIG. 16 illustrates a cross-sectional view of MTJ device 100 of FIG. 15 after performing subsequent processing steps, in accordance with at least one embodiment of the present invention.

FIG. 17 illustrates a cross-sectional view of MTJ device 100 of FIG. 16 after performing subsequent processing steps, in accordance with at least one embodiment of the present invention.

FIG. 18 illustrates a cross-sectional view of MTJ device 100 of FIG. 17 after performing subsequent processing steps, in accordance with at least one embodiment of the present invention.

### DETAILED DESCRIPTION

The present invention generally relates to fabrication methods and structures for magnetic tunnel junction (MTJ) devices, and more specifically, to fabrication methods and structures for MTJ devices having an encased free layer.

An MTJ device, which is a primary storage element in a magnetoresistive random-access memory (MRAM), is a magnetic storage and switching device in which two ferromagnetic layers are separated by a thin non-magnetic insulating layer (i.e., a tunnel barrier) to form a stacked structure. One of the ferromagnetic layers of the MTJ device has a magnetization that is fixed, and it is therefore referred to as a magnetic fixed layer (or reference layer). The other ferromagnetic layer has a magnetization that can change, and it is therefore referred to as a magnetic free layer (or free layer). This configuration is known as a magnetic tunnel junction (MTJ) pillar. Conventional MTJ pillar structures may include a cobalt (Co)-based synthetic anti-ferromagnet (SAF), a CoFeB-based reference layer, a MgO-based tunnel barrier, a CoFeB-based free layer, and metal cap layers containing materials such as tantalum (Ta) and/or ruthenium (Ru).

For high performance MRAM devices based on perpendicular MTJ pillars, well-defined interfaces and interface control are essential. Typically, MTJ pillars are formed by subtractive patterning of blanket MTJ stacks in between two interconnect levels using, for example, reactive ion etching (RIE) or ion beam etching (IBE). However, the patterning of blanket MTJ stacks to form MTJ pillars presents a major challenge, as it typically leads to electrical shorts between neighboring MTJ pillars due to re-sputtering of thick bottom metal layers onto the MTJ pillar sidewalls during the etching process. After patterning the blanket MTJ stacks to form the MTJ pillars, the inter-pillar spaces are filled with an interlayer dielectric (ILD) to electrically isolate the MTJ pillars. However, due to the high aspect ratio of these inter-pillar spaces, this gap fill process typically results in the formation of voids in the ILD, which can also lead to electrical shorts between neighboring MTJ pillars.

Embodiments of the present disclosure provide an MRAM device with an embedded MTJ pillar structure, and a method of making the same, which improve upon the foregoing deficiencies of conventional MTJ pillar manufacturing. Rather than the conventional practice of patterning a blanket MTJ stack, and subsequently filling the inter-pillar gaps with an ILD in a single gap fill step, embodiments of the present invention form an MTJ pillar and fill the inter-pillar gaps in a stepwise manner.

According to embodiments of the present invention, an initial material stack including a bottom electrode layer and a reference layer are patterned (e.g., using lithography and etching) to form a first portion of a pillar structure including a bottom electrode and a reference layer formed on top thereof. The sidewall surfaces of the bottom electrode and reference layer are then covered with a dielectric encapsulation layer, and an interlayer dielectric is formed within the inter-pillar gaps located between this initial pillar structure and similar neighboring pillar structures. Since these inter-pillar gaps have a low aspect ratio at this stage of the manufacturing process, the risk of electrical shorts between neighboring MTJ devices caused by voids formed in the interlayer dielectric is reduced. Furthermore, by patterning the bottom electrode layer and reference layer prior to depositing the free layer, tunnel barrier layer and top electrode layer, re-sputtering of conductive metal particles onto the sidewall surfaces of the tunnel barrier layer and free layer during the patterning of the bottom electrode layer and reference layer is eliminated. This will reduce the risk of tunnel barrier electrical shorts which is a common failure mode in traditional MTJ configurations, thereby increasing device reliability.

After forming the first portion of the pillar structure including the bottom electrode and reference layer, a second portion of the pillar structure including a dielectric layer, tunnel barrier layer, free layer, and top electrode is formed. In forming the second portion of the pillar structure, a dielectric layer is formed on top of the reference layer, and an opening is formed that extends completely through the dielectric layer and partially through the reference layer. The opening is lined with a tunnel barrier layer, a free layer is formed within the opening lined with the tunnel barrier layer, and a top electrode layer is formed on top thereof. Thus, it can be said that the bottom and sidewall surfaces of the free layer are encased by the tunnel barrier layer, and that the encased structure is embedded within the dielectric layer and a recessed area of the reference layer. By encasing the bottom and sidewall surfaces of the free layer with the tunnel barrier layer, and embedding the entire encased structure within the dielectric layer and partially within the recessed portion of the reference layer prior to patterning the top electrode layer, re-sputtering of conductive metal particles from the top electrode onto the sidewall surfaces of the tunnel barrier layer and free layer is prevented during the patterning process. This will also reduce the risk of tunnel barrier electrical shorts which is a common failure mode in traditional MTJ configurations, thereby again increasing device reliability.

Furthermore, after forming the second portion of the pillar structure, an additional interlayer dielectric may be formed within the inter-pillar gaps located between the second portion of the pillar structure and similar neighboring pillar structures. Since these inter-pillar gaps also have a low aspect ratio at this stage of the manufacturing process, the risk of electrical shorts between neighboring MTJ devices caused by voids formed in the interlayer dielectric is reduced.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this invention may be embodied in many different forms and should not be construed as limited to the exemplary embodiments set forth herein. Rather, these exemplary embodiments are provided so that this invention will be thorough and complete and will fully convey the scope of this invention to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

As used herein, terms such as “depositing,” “forming,” and the like may refer to the disposition of layers, or portions of materials, in accordance with a given embodiment. Such processes may or may not be different than those used in the standard practice of the art of semiconductor device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, micromachining, microetching, wet and/or dry etching processes, plasma etching processes, or any of the known etching processes in which material is removed.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

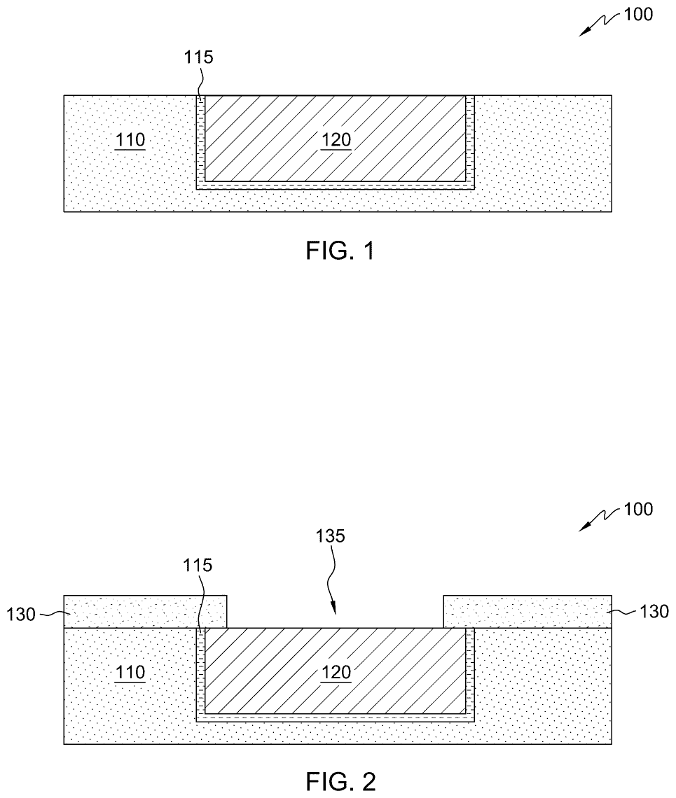

The present invention will now be described in detail with reference to the Figures, in which like numbers represent the same or similar elements. FIGS. 1-18 include various cross-sectional views depicting illustrative steps of methods for manufacturing MTJ devices and the resulting MTJ devices according to select embodiments of the present invention. One having ordinary skill in the art will appreciate that there are many options available for the formation of the structures described herein and that the following discussion does not limit embodiments to only the techniques described herein.

FIG. 1 depicts a cross-sectional view of a magnetic tunnel junction (MTJ) device 100 at an intermediate step during a semiconductor manufacturing process, in accordance with at least one embodiment of the present invention. The MTJ device 100 may be part of any MTJ-containing device, including, but not limited to, MRAM, spin-transfer torque (STT) MRAM, and spin-orbit torque (SOT) MRAM. In an embodiment, MTJ device 100 is an MRAM device based on a perpendicular MTJ pillar structure.

In assembly of MTJ device 100 of FIG. 1, a lower electrically conductive structure 120 is formed within an interlayer dielectric (ILD) layer 110. Collectively, the lower electrically conductive structure 120 and the ILD layer 110 are part of an interconnect level. It should be noted that one or more additional back-end-of-the-line (BEOL) interconnect levels and/or middle-of-the-line (MOL) interconnect levels may be located beneath this interconnect level. These other levels are not shown for clarity.

The ILD layer 110 may be formed by depositing a dielectric material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. The ILD layer 110 may be composed of an inorganic dielectric material or an organic dielectric material. Examples of suitable dielectric materials that may be employed as the ILD layer 110 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl. In some embodiments, the ILD layer 110 may have a dielectric constant (all dielectric constants mentioned herein are measured relative to a vacuum, unless otherwise stated) that is about 4.0 or less. In an embodiment, the ILD layer 110 may have a dielectric constant of 2.8 or less. Dielectric materials having a dielectric constant of 2.8 or less generally have a lower parasitic cross talk as compared to dielectric materials whose dielectric constant is greater than 4.0. In some embodiments, the ILD layer 110 may be porous. In other embodiments, the ILD layer 110 may be non-porous.

The lower electrically conductive structure 120 may be formed within the ILD layer 110 using one or more conventional BEOL semiconductor manufacturing processes (e.g., a damascene process or a dual damascene process) as known by one of ordinary skill in the art, and as such, a more detailed description of such processes is not presented herein. The lower electrically conductive structure 120 may include a conductive material including, but not limited to, copper (Cu), aluminum (Al), ruthenium (Ru), rhodium (Rh), iridium (Ir), tantalum (Ta), tantalum nitride (TaN) titanium (Ti), titanium nitride (TiN), tungsten (W), molybdenum (Mo), nickel (Ni), or any combination thereof.

In some embodiments, and as depicted in FIG. 1, a diffusion barrier liner 115 is formed along the bottom and sidewall surfaces of an opening (not depicted) formed within the ILD layer 110. The diffusion barrier liner 115 is composed of a diffusion barrier material (i.e., a material that serves as a barrier to prevent a conductive material used to form the lower electrically conductive structure 120 from diffusing into the ILD layer 110). The diffusion barrier liner 115 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN), or combinations of barrier materials such as RuTaN, Ta/TaN, CoWP, NiMoP, or NiMoB which are suitable for the given application.

FIG. 2 illustrates a cross-sectional view of MTJ device 100 of FIG. 1 after performing subsequent processing steps, in accordance with at least one embodiment of the present invention. In assembly of MTJ device 100 of FIG. 2, a dielectric capping layer 130 is formed, followed by the patterning of the dielectric capping layer 130 to form an opening 135 within the dielectric capping layer 130.

The dielectric capping layer 130 may be formed by depositing a dielectric capping material onto the ILD layer 110, diffusion barrier liner 115, and lower electrically conductive structure 120 using known deposition techniques, including, but not limited to, chemical vapor deposition (CVD), plasma enhanced chemical vapor deposition (PECVD), atomic layer deposition (ALD), physical vapor deposition (PVD), sputtering, chemical solution deposition, or plating. Suitable dielectric capping materials for the dielectric capping layer 130 may include, but are not limited to, silicon carbide (SiC), silicon nitride (Si₃N₄), a nitrogen and hydrogen doped silicon carbide (SiC(N,H)), or any combination thereof.

Following the formation of the dielectric capping layer 130, the dielectric capping layer 130 is etched using one or more conventional patterning processes (e.g., lithography and etching) to form an opening 135 in the dielectric capping layer 130. For example, a hard mask material (e.g., silicon nitride, titanium nitride, tantalum nitride, or any suitable inorganic metal-containing material) is deposited (e.g., utilizing known techniques including, but not limited to, chemical vapor deposition (CVD), plasma enhanced chemical vapor deposition (PECVD), atomic layer deposition (ALD), physical vapor deposition (PVD), or sputtering) onto the dielectric capping layer 130, and the hard mask material is patterned to form a patterned hard mask (not depicted). Then, using the patterned hard mask, the dielectric capping layer 130 is etched (using, for example, reactive ion etching (RIE), ion beam etching (IBE), chemical wet etching, or a combination of IBE and chemical wet etching) to form the opening 135 within the dielectric capping layer 130 that exposes at least a portion of the top surface of the lower electrically conductive structure 120.

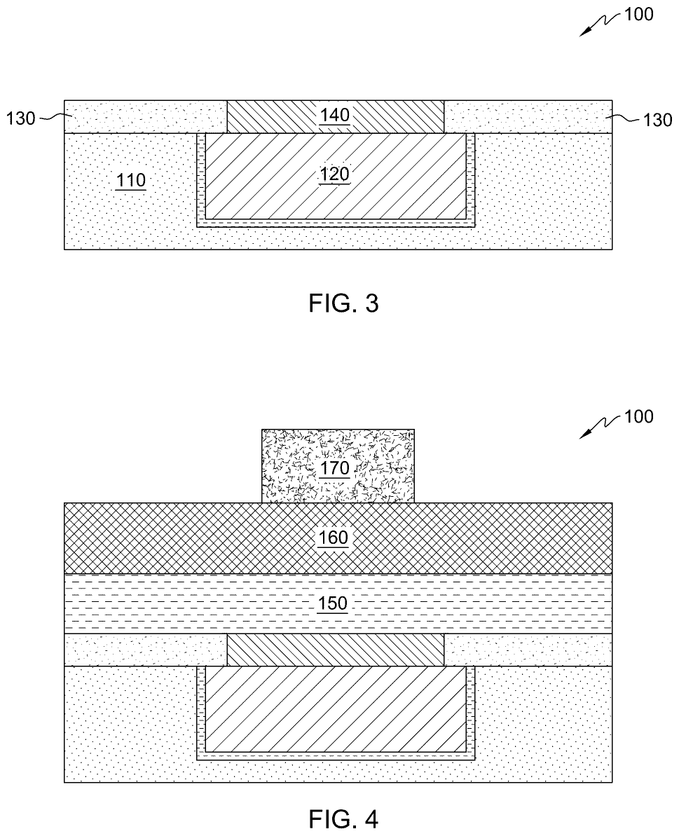

FIG. 3 illustrates a cross-sectional view of MTJ device 100 of FIG. 2 after performing subsequent processing steps, in accordance with at least one embodiment of the present invention. In assembly of MTJ device 100 of FIG. 3, a metal cap 140 is formed on top of the lower electrically conductive structure 120.

The metal cap 140 may be formed by depositing a metal cap material onto the top surface of the dielectric capping layer 130, and on the bottom and sidewall surfaces of the opening 135 (depicted in FIG. 2) formed within the ILD layer 110 using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable metal cap materials for the metal cap 140 may include, but are not limited to, niobium (Nb), tungsten (W), tantalum (Ta), titanium (Ti), ruthenium (Ru), or any combination thereof.

Following the deposition of the metal cap material, a planarization process such as, for example, chemical mechanical planarization or polishing (CMP), and/or grinding, may subsequently be performed to remove portions of the metal cap material located above the top surface of the dielectric capping layer 130. The planarization stops at the top surface of the dielectric capping layer 130, such that the top surface of the metal cap 140 is substantially coplanar with the top surface of the dielectric capping layer 130.

FIG. 4 illustrates a cross-sectional view of MTJ device 300 of FIG. 3 after performing subsequent processing steps, in accordance with at least one embodiment of the present invention. In assembly of MTJ device 100 of FIG. 4, a material stack including a bottom electrode layer 150 and a reference layer 160 (i.e., a magnetic fixed layer or fixed layer) is formed, followed by the formation of a patterned hard mask 170 on top of the reference layer 160.

The bottom electrode layer 150 and reference layer 160 may be formed by depositing respective electrode materials and reference layer materials using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable electrode materials for the bottom electrode layer 150 may be composed of a conductive material including, but not limited to, copper (Cu), aluminum (Al), ruthenium (Ru), rhodium (Rh), iridium (Ir), tantalum (Ta), tantalum nitride (TaN), titanium (Ti), titanium nitride (TiN), tungsten (W), molybdenum (Mo), or any combination thereof.

The reference layer 160 has a fixed magnetization and includes a metal or metal alloy (or a stack thereof) that exhibits a high spin polarization. Suitable reference layer materials for the reference layer 160 may include, but are not limited to, metals such as iron (Fe) boron (B), platinum (Pt), nickel (Ni), tungsten (W), or iridium (Ir), metal alloys such as cobalt-iron (CoFe), cobalt-iron-nickel (CoFeNi), iron-boron (FeB), cobalt-iron-boron (CoFeB), or any combination thereof. In some embodiments, the reference layer 160 may be a multilayer arrangement having (i) a high spin polarization region formed from a metal or metal alloy mentioned above, and (ii) a strong perpendicular magnetic anisotropy (PMA) region formed from a metal or metal alloy that exhibits a strong PMA. Suitable metals that exhibit a strong PMA may include, but are not limited to, cobalt (Co), nickel (Ni), platinum (Pt), palladium (Pd), iridium (Ir), or Ruthenium (Ru), and may be arranged as alternating layers. Suitable metal alloys that exhibit a strong PMA may include, but are not limited to, cobalt-iron-terbium (CoFeTb), cobalt-iron-gadolinium (Co—Fe—Gd), cobalt-chromium-platinum (CoCrPt), cobalt-platinum (CoPt), cobalt-palladium (CoPd), iron-platinum (FePt), or iron-palladium (FePd), and may be arranged as alternating layers.

By way of example, the patterned hard mask 170 may be formed as follows. A hard mask material (e.g., silicon nitride, titanium nitride, tantalum nitride, or any suitable inorganic metal-containing material) is deposited onto the top surface of the reference layer 160, followed by the deposition of photoresist material (not depicted) on top thereof using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. A photomask (not depicted) patterned with shapes defining the patterned structure to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the hard mask material. Dry etch techniques (for example, an anisotropic etch process, such as reactive ion etch) may be employed to selectively remove portions of the hard mask material to form the patterned hard mask 170. After formation of the patterned hard mask 170, the photoresist material may be stripped from the patterned hard mask 170 by ashing or other suitable processes. The resulting structure may be subjected to a wet clean.

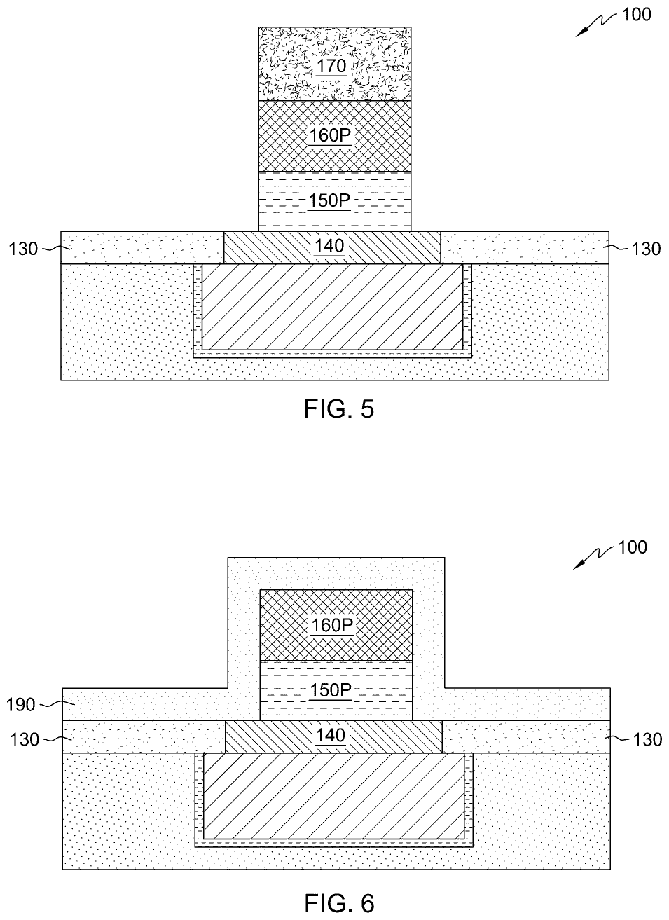

FIG. 5 illustrates a cross-sectional view of MTJ device 100 of FIG. 4 after performing subsequent processing steps, in accordance with at least one embodiment of the present invention. In assembly of MTJ device 100 of FIG. 5, the patterned hard mask 170 is used to pattern the bottom electrode layer 150 (depicted in FIG. 4) and reference layer 160 (depicted in FIG. 4). The resulting patterned bottom electrode layer 150 and patterned reference layer 160 shall hereinafter be referred to as bottom electrode 150P and reference layer 160P.

During patterning of the bottom electrode layer 150 and reference layer 160 using the patterned hard mask 170, the physically exposed portions of the bottom electrode layer 150 and reference layer 160 are removed by an anisotropic etching process (e.g., reactive ion etching (RIE), ion beam etching (IBE), chemical wet etching, or any combination thereof). The etching of the bottom electrode layer 150 and reference layer 160 can be controlled by a timed etching process as known by one of ordinary skill in the art, such that the etching process is terminated upon reaching the top surfaces of the dielectric capping layer 130 and metal cap 140, respectively. As depicted by FIG. 5, the etching process results in a reduction in the width of the bottom electrode layer 150 and the reference layer 160, such that the bottom electrode 150P and the reference layer 160P are entirely located above the metal cap 140.

FIG. 6 illustrates a cross-sectional view of MTJ device 100 of FIG. 5 after performing subsequent processing steps, in accordance with at least one embodiment of the present invention. In assembly of MTJ device 100 of FIG. 6, the patterned hard mask 170 (depicted in FIG. 5) is removed, and a dielectric encapsulation layer 190 is formed onto the physically exposed surfaces of the dielectric capping layer 130, metal cap 140, bottom electrode 150P, and reference layer 160P.

After removal of the patterned hard mask 170 (depicted in FIG. 5) using one or more processes as known by one of ordinary skill in the art, the dielectric encapsulation layer 190 may be formed by conformally depositing a dielectric material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable dielectric materials used to form the dielectric encapsulation layer 190 may include, but are not limited to, silicon carbide (SiC), silicon nitride (Si₃N₄), silicon dioxide (SiO₂) aluminum oxide (Al₂O₃), amorphous carbon (a-C), silicon silicoboron carbonitride (SiOCN), silicon oxcycarbonitride (SiOCN), or any combination thereof. As depicted by FIG. 6, the dielectric encapsulation layer 190 is formed on the physically exposed top surfaces of the dielectric capping layer 130, metal cap 140, and reference layer 160P, as well as on the sidewall surfaces of the bottom electrode 150P and reference layer 160P.

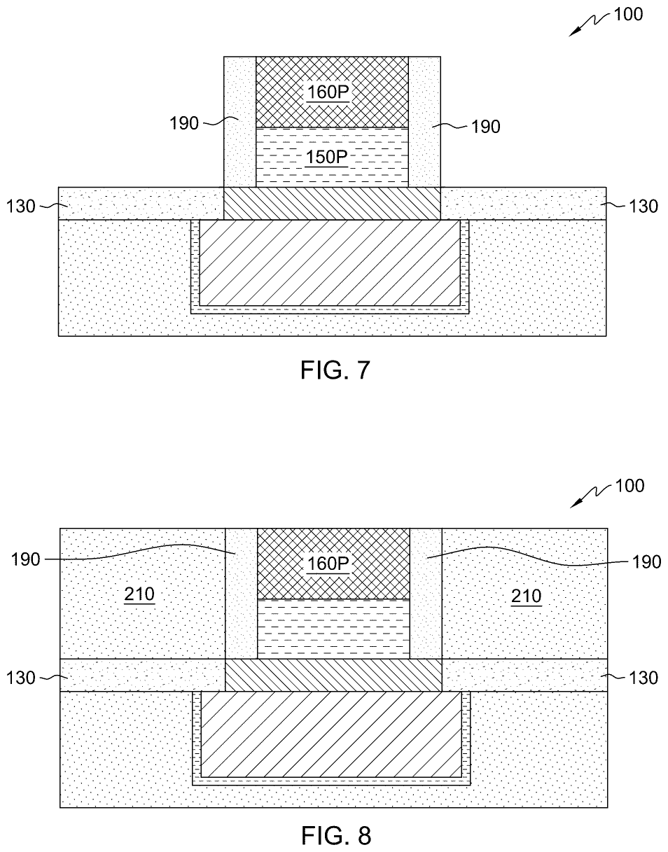

FIG. 7 illustrates a cross-sectional view of MTJ device 100 of FIG. 6 after performing subsequent processing steps, in accordance with at least one embodiment of the present invention. In assembly of MTJ device 100 of FIG. 7, an etch back of the dielectric encapsulation layer 190 is performed, for example, using a directional anisotropic etching process as known by one of ordinary skill in the art. The etching process removes the respective portions of the dielectric encapsulation layer 190 formed above the dielectric capping layer 130 and the reference layer 160P. The etching of the dielectric encapsulation layer 190 can be controlled by a timed etching process as known by one of ordinary skill in the art, such that the etching process is terminated upon reaching the top surfaces of the dielectric capping layer 130 and reference layer 160P, respectively. As depicted by FIG. 7, after the etch back of the dielectric encapsulation layer 190, the sidewall surfaces of the bottom electrode 150P and reference layer 160P remain covered by the dielectric encapsulation layer 190.

FIG. 8 illustrates a cross-sectional view of MTJ device 100 of FIG. 7 after performing subsequent processing steps, in accordance with at least one embodiment of the present invention. In assembly of MTJ device 100 of FIG. 8, an interlayer dielectric (ILD) layer 210 is formed by depositing a dielectric material onto the physically exposed surfaces of the dielectric capping layer 130, dielectric encapsulation layer 190, and reference layer 160P, followed by a planarization process. As depicted by FIG. 8, the ILD layer 210 is composed of a dielectric material that is compositionally different than the dielectric material of the dielectric encapsulation layer 190.

The dielectric material of the ILD layer 210 may be deposited using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition, and may include any of the dielectric materials previously described with respect to the ILD layer 110 of FIG. 1. Following the deposition of the dielectric material, a planarization process such as, for example, chemical mechanical planarization or polishing (CMP), and/or grinding, may subsequently be performed to remove any of the dielectric material located above the top surfaces of the reference layer 160P and dielectric encapsulation layer 190, such that the top surface of the ILD layer 210 is substantially coplanar with the top surfaces of the reference layer 160P and dielectric encapsulation layer 190.

As further depicted by FIG. 8, the ILD layer 210 is formed in the inter-pillar gaps that are laterally adjacent to the pillar structure of MTJ device 100, such that the ILD layer 210 laterally surrounds the sidewall surfaces of the dielectric encapsulation layer 190. In other words, the ILD layer 210 is formed in the gaps between MTJ device 100 and other adjacent MTJ devices (not depicted) formed at this stage in the semiconductor fabrication process. It should be appreciated that due to the low aspect ratio of the inter-pillar gaps at this stage in the semiconductor manufacturing process, the likelihood of voids being formed when filling the inter-pillar gaps is reduced, which ultimately results in a reduced risk of electrical shorts between the MTJ device 100 and other neighboring MTJ devices.

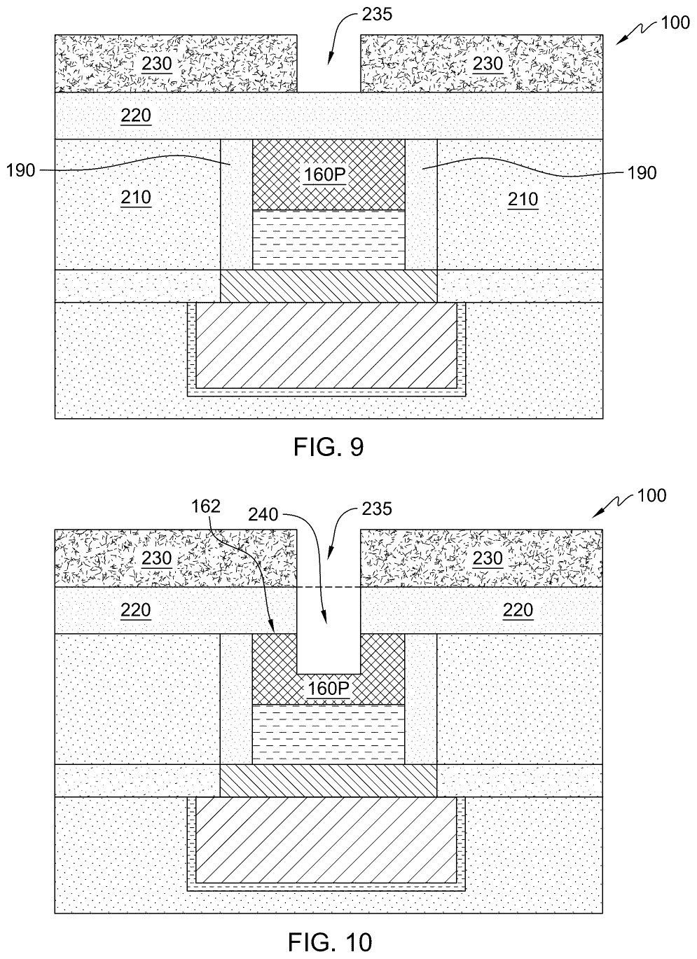

FIG. 9 illustrates a cross-sectional view of MTJ device 100 of FIG. 8 after performing subsequent processing steps, in accordance with at least one embodiment of the present invention. In assembly of MTJ device 100 of FIG. 9, a dielectric layer 220 is formed on the respective top surfaces of the reference layer 160P, dielectric encapsulation layer 190, and ILD layer 210, and a patterned hard mask 230 is formed on top of the dielectric layer 220.

The respective materials used to form the dielectric layer 220 and the patterned hard mask 230 may be deposited using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable dielectric materials that can be used to form the dielectric layer 220 may include, but are not limited to, silicon nitride (SiN), aluminum oxide (Al₂O₃), amorphous carbon (a-C), silicoboron carbonitride (SiOCN), silicon oxcycarbonitride (SiOCN), or any combination thereof. In some embodiments, and as depicted by FIG. 9, the dielectric encapsulation layer 190 and the dielectric layer 220 are formed from compositionally similar dielectric materials. However, in other embodiments (not depicted), the dielectric encapsulation layer 190 and the dielectric layer 220 may be formed from compositionally different dielectric materials. As further depicted by FIG. 9, the dielectric layer 220 is composed of a dielectric material that is compositionally different than the dielectric material of the ILD layer 210. Suitable hard mask materials that can be used to form the patterned hard mask 230 may include, but are not limited to, silicon nitride (SiN), titanium nitride (TiN), tantalum nitride (TaN), or any suitable inorganic metal-containing material.

The hard mask material deposited on top of the dielectric layer 220 may be patterned to form the patterned hard mask 230 using the same patterning process (e.g., lithography and etching) as previously described with respect to forming the patterned hard mask 170 of FIG. 4. The patterning of the hard mask material to form the patterned hard mask 230 further results in the formation of an opening 235 that extends completely through the hard mask material, such that the opening 235 exposes a portion of the top surface of the dielectric layer 220 located above the reference layer 160P.

FIG. 10 illustrates a cross-sectional view of MTJ device 100 of FIG. 9 after performing subsequent processing steps 1100, in accordance with at least one embodiment of the present invention. In assembly of MTJ device 100 of FIG. 10, an opening 240 is formed in the dielectric layer 220 and the reference layer 160P.

The opening 240 in the dielectric layer 220 and the reference layer 160P may be formed, for example, as follows. Using the patterned hard mask 230, which acts as an etch mask, the physically exposed portions of the dielectric layer 220 and the reference layer 160P located below the opening 235 in the patterned hard mask 230 are removed by an anisotropic etching process (e.g., reactive ion etching (RIE), ion beam etching (IBE), chemical wet etching, or any combination thereof) to form the opening 240 within the dielectric layer 220 and reference layer 160P. The etching of the dielectric layer 220 and the reference layer 160P can be controlled by a timed etching process as known by one of ordinary skill in the art, such that the etching process is terminated upon reaching a desired depth below the top surface 162 of the reference layer 160P. As depicted by FIG. 10, the opening 240 is essentially an extension of the opening 235 in the patterned hard mask 230, in which the opening 240 extends completely through the dielectric layer 220, and partially through the reference layer 160P.

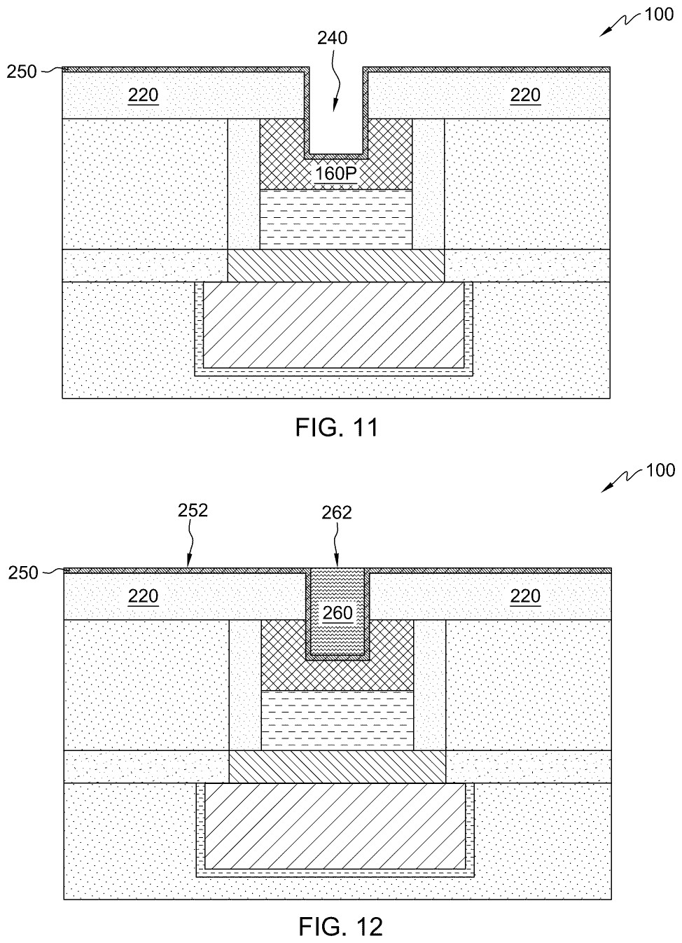

FIG. 11 illustrates a cross-sectional view of MTJ device 100 of FIG. 10 after performing subsequent processing steps, in accordance with at least one embodiment of the present invention. In assembly of MTJ device 100 of FIG. 11, the patterned hard mask 230 (depicted in FIG. 10) is removed, and a tunnel barrier layer 250 is formed on the top surface of dielectric layer 220, and along the bottom and sidewall surfaces of opening 240.

After removal of the patterned hard mask 230 (depicted in FIG. 10) using one or more processes as known by one of ordinary skill in the art, the tunnel barrier 250 layer, which magnetically decouples the reference layer 160P and the free layer 260, may be formed by conformally depositing a tunnel barrier material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable tunnel barrier materials used to form the tunnel barrier layer 250 may include a non-magnetic insulator such as magnesium oxide (MgO), aluminum oxide (e.g., Al₂O₃), titanium oxide, gadolinium oxide, tantalum oxide, molybdenum oxide, tungsten oxide, or any combination thereof. As depicted by FIG. 11, the tunnel barrier layer 250 is formed on top of the dielectric layer 220, and along the bottom and sidewall surfaces of the opening 240 formed within the dielectric layer 220 and the reference layer 160P. Thus, it can be said that the opening 240 that extends completely through the dielectric layer 220 and partially through the reference layer 160P is lined with the tunnel barrier layer 250, such that the tunnel barrier layer 250 forms a hollow cylindrical structure within the opening 240.

FIG. 12 illustrates a cross-sectional view of MTJ device 100 of FIG. 11 after performing subsequent processing steps 1100, in accordance with at least one embodiment of the present invention. In assembly of MTJ device 100 of FIG. 12, a free layer 260 (i.e., magnetic free layer) is formed on top of the tunnel barrier layer 250 and within the opening 240, followed by a planarization process.

The free layer 260 may be composed of a magnetic material (or stack of magnetic materials) having a magnetization that can be switched in orientation relative to the magnetization orientation of the reference layer 160P. The free layer 260 may be formed by depositing a free layer material on top of the tunnel barrier layer 250 formed above the dielectric layer 220, and within the opening 240 (depicted in FIG. 11) lined with the tunnel barrier layer 250, using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable free layer materials used to form the free layer 260 may include, but are not limited to, metals such as cobalt (Co), Iron (Fe), Boron (B), or any combination thereof, and metal alloys such cobalt-iron (CoFe), iron-boron (FeB), cobalt-iron-boron (CoFeB), or any combination thereof.

Following the deposition of the free layer material, a planarization process such as, for example, chemical mechanical planarization or polishing (CMP), and/or grinding, may subsequently be performed to remove portions of the free layer material located above the top surface 252 of the tunnel barrier layer 250. The planarization stops at the top surface 252 of the tunnel barrier layer 250, such that the top surface 262 of the free layer 260 is substantially coplanar with the top surface 252 of the tunnel barrier layer 250. As depicted by FIG. 12, the tunnel barrier layer 250 is located on the top surface of the dielectric layer 220, and along the bottom and sidewall surfaces of the free layer 260. Thus, it can be said that the bottom and sidewall surfaces of the free layer 260 are completely encased by the tunnel barrier layer 250.

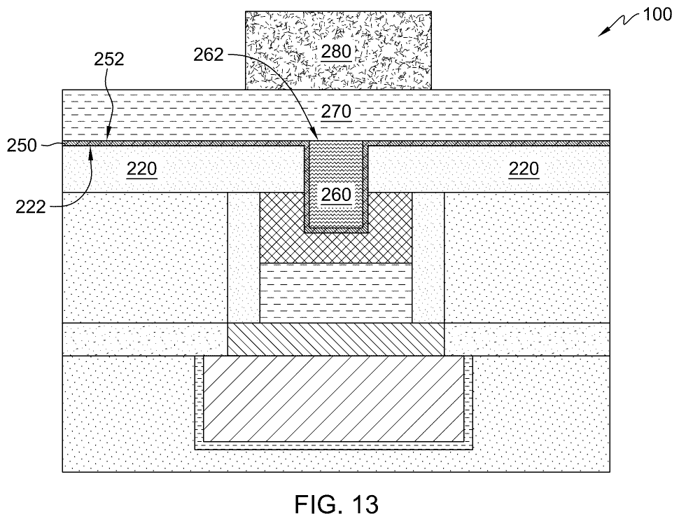

FIG. 13 illustrates a cross-sectional view of MTJ device 100 of FIG. 12 after performing subsequent processing steps, in accordance with at least one embodiment of the present invention. In assembly of MTJ device 100 of FIG. 13, a top electrode layer 270 is formed on the top surfaces 252, 262 of the tunnel barrier layer 250 and the free layer 260, followed by the formation of a patterned hard mask 280 on top of the top electrode layer 270.

The top electrode layer 270 and patterned hard mask 280 may be formed by depositing respective electrode and hard mask materials using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable electrode materials for the top electrode 270 may include a metal, metal alloy, or metal containing compound such as copper (Cu), aluminum (Al), ruthenium (Ru), rhodium (Rh), iridium (Ir), tantalum (Ta), tantalum nitride (TaN), titanium (Ti), titanium nitride (TiN), tungsten (W), molybdenum (Mo), or any combination thereof. In some embodiments, and as depicted by FIG. 13, the bottom electrode layer 150 (depicted in FIG. 4) and the top electrode layer 270 are formed from the same materials. However, in other embodiments (not shown), the bottom electrode layer 150 and the top electrode layer 270 may be formed from different materials. Suitable hard mask materials that can be used to form the patterned hard mask 280 may include, but are not limited to, silicon nitride (SiN), titanium nitride (TiN), tantalum nitride (TaN), or any suitable inorganic metal-containing material. The hard mask material may be patterned to form the patterned hard mask 280 using the same patterning process (e.g., lithography and etching) as previously described with respect to the patterned hard mask 170 of FIG. 4.

In some embodiments (not depicted), an additional etch back of the free layer 260 is performed (e.g., by performing additional lithography and etching steps) to recess the top surface 262 of the free layer 260 below the top surface 222 of the dielectric layer 220. In these embodiments, a bottom portion of the bottom electrode layer 270 is formed within the recessed area above the free layer 260. Thus, sidewall surfaces of the portion of the bottom electrode layer located below the top surface 252 of the tunnel barrier layer 250 are also encased by the tunnel barrier layer 250.

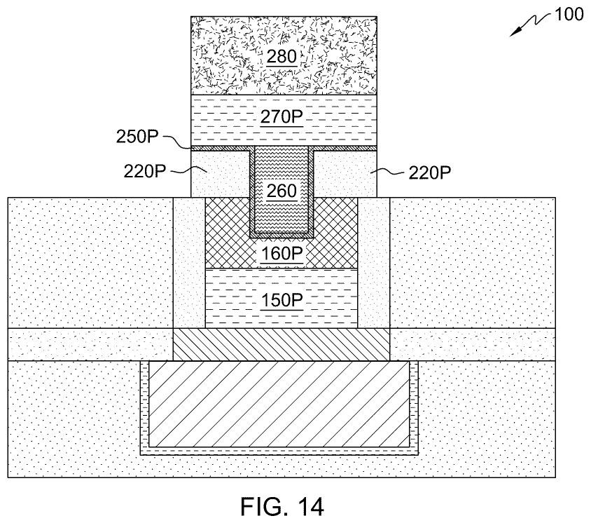

FIG. 14 illustrates a cross-sectional view of MTJ device 100 of FIG. 13 after performing subsequent processing steps, in accordance with at least one embodiment of the present invention. In assembly of MTJ device 100 of FIG. 14, the patterned hard mask 280 is used to pattern the dielectric layer 220 (depicted in FIG. 13), the tunnel barrier layer 250 (depicted in FIG. 13), and the top electrode layer 270 (depicted in FIG. 13).

During patterning of the dielectric layer 220, tunnel barrier layer 250, and top electrode layer 270 using the patterned hard mask 280, the physically exposed portions of the dielectric layer 220, tunnel barrier layer 250, and top electrode layer 270 are removed by an anisotropic etching process (e.g., reactive ion etching (RIE), ion beam etching (IBE), chemical wet etching, or any combination thereof). The etching of the dielectric layer 220, tunnel barrier layer 250, and top electrode layer 270 can be controlled by a timed etching process as known by one of ordinary skill in the art, such that the etching process is terminated upon reaching the top surfaces of the dielectric encapsulation layer 190 and ILD layer 210, respectively. The resulting patterned dielectric layer 220, tunnel barrier layer 250, and top electrode layer 270 shall hereinafter be referred to as dielectric layer 220P, tunnel barrier layer 250P, and top electrode 270P.

It should be appreciated that by encasing the bottom and sidewall surfaces of the free layer 260 with the tunnel barrier layer 250, and embedding the entire encased structure within the dielectric layer 220 and partially within the recessed portion of the reference layer 160 prior to patterning the top electrode layer 270, back sputtering of conductive metal particles from the top electrode layer 270 onto the sidewall surfaces of the tunnel barrier layer 250 and free layer 260 can be prevented during the patterning process. It should be further noted that due to the geometry of the MTJ device 100 and the processing steps used in forming the same, no re-sputtered conductive metal particles from the bottom electrode 150P or reference layer 160P are present on sidewall surfaces of the tunnel barrier layer 250P and the free layer 260. As such, electrical shorting of the MTJ device 100 caused by re-sputtering of conductive metal particles onto the sidewall surfaces of MTJ device 100 during patterning of the bottom electrode 150P and reference layer 160P is eliminated.

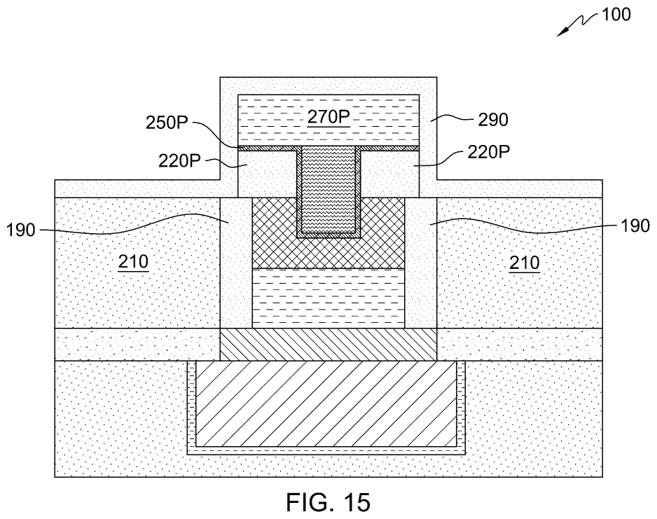

FIG. 15 illustrates a cross-sectional view of MTJ device 100 of FIG. 14 after performing subsequent processing steps, in accordance with at least one embodiment of the present invention. In assembly of MTJ device 100 of FIG. 15, the patterned hard mask 280 (depicted in FIG. 14) is removed, and a dielectric encapsulation layer 290 is formed onto the physically exposed surfaces of the dielectric encapsulation layer 190, ILD layer 210, dielectric layer 220P, tunnel barrier layer 250P, and top electrode 270P.

After removal of the patterned hard mask 280 (depicted in FIG. 14) using one or more processes as known by one of ordinary skill in the art, the dielectric encapsulation layer 290 may be formed by conformally depositing a dielectric material using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition. Suitable dielectric materials used to form the dielectric encapsulation layer 290 may include, but are not limited to, silicon carbide (SiC), silicon nitride (Si₃N₄), silicon dioxide (SiO₂) aluminum oxide (Al₂O₃), amorphous carbon (a-C), silicon silicoboron carbonitride (SiOCN), silicon oxcycarbonitride (SiOCN), or any combination thereof. As depicted by FIG. 15, the dielectric encapsulation layer 290 is formed on the physically exposed top surfaces of the dielectric encapsulation layer 190, ILD layer 210, and top electrode 270P, as well as on the sidewall surfaces of the dielectric layer 220P, tunnel barrier layer 250P, and top electrode 270P. In some embodiments, and as depicted by FIG. 15, the dielectric encapsulation layer 190, dielectric layer 220P, and dielectric encapsulation layer 290 are formed from compositionally similar dielectric materials.

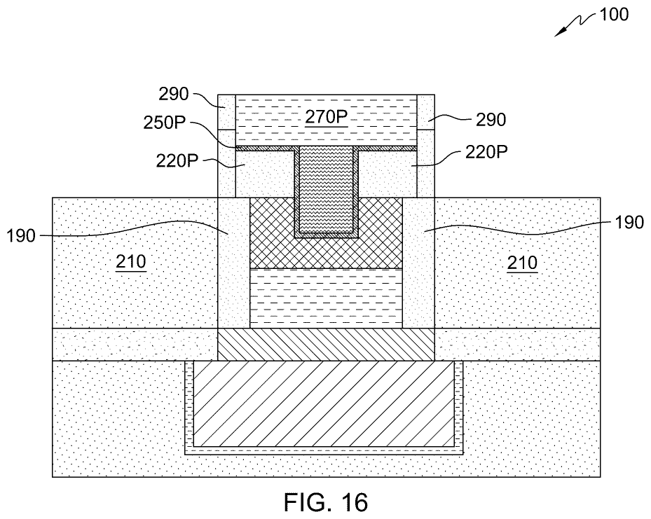

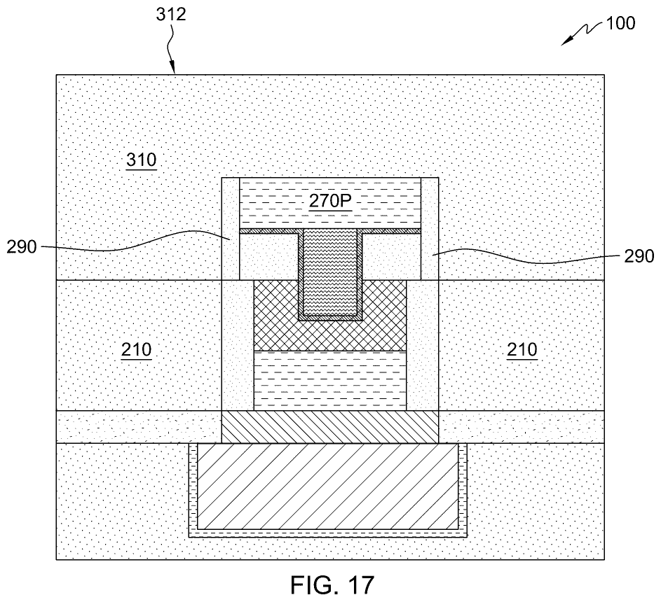

FIG. 16 illustrates a cross-sectional view of MTJ device 100 of FIG. 15 after performing subsequent processing steps, in accordance with at least one embodiment of the present invention. In assembly of MTJ device 100 of FIG. 16, an etch back of the dielectric encapsulation layer 290 is performed, for example, using a directional anisotropic etching process as known by one of ordinary skill in the art. The etching process removes the respective portions of the dielectric encapsulation layer 290 formed above the dielectric encapsulation layer 190, ILD layer 210, and top electrode 270P. The etching of the dielectric encapsulation layer 290 can be controlled by a timed etching process as known by one of ordinary skill in the art, such that the etching process is terminated upon reaching the top surfaces of the ILD layer 210 and top electrode 270P, respectively. As depicted by FIG. 16, after the etch back of the dielectric encapsulation layer 290, the sidewall surfaces of the dielectric layer 220P, tunnel barrier layer 250P, and the top electrode 270P remain covered by the dielectric encapsulation layer 290.

FIG. 17 illustrates a cross-sectional view of MTJ device 100 of FIG. 16 after performing subsequent processing steps, in accordance with at least one embodiment of the present invention. In assembly of MTJ device 100 of FIG. 17, an interlayer dielectric (ILD) layer 310 is formed by depositing a dielectric material onto the physically exposed surfaces of the ILD layer 210, dielectric encapsulation layer 290, and top electrode 270P, followed by a planarization process. As depicted by FIG. 17, the ILD layer 310 is composed of a dielectric material that is compositionally similar to the dielectric material of ILD layer 210, but compositionally different than the dielectric material of the dielectric encapsulation layer 290.

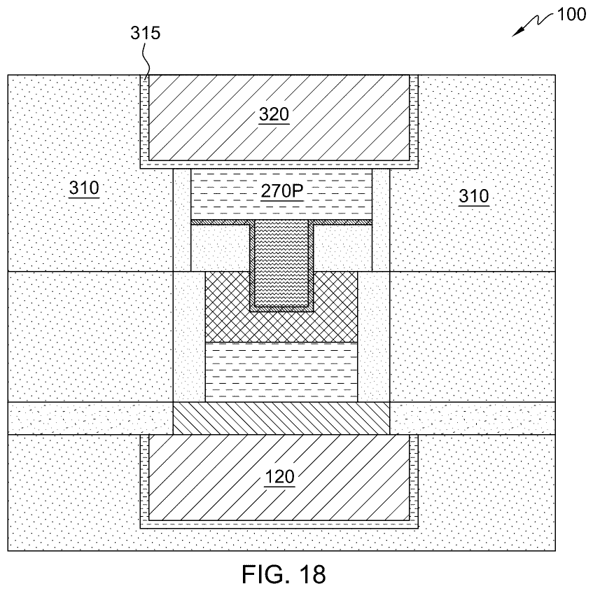

The dielectric material of the ILD layer 310 may be deposited using known deposition techniques including, but not limited to, chemical vapor deposition (CVD), plasma enhanced chemical vapor deposition (PECVD), atomic layer deposition (ALD), physical vapor deposition (PVD), sputtering, or chemical solution deposition, and may include any of the dielectric materials previously described with respect to the ILD layer 110 of FIG. 1. Following the deposition of the dielectric material, a planarization process such as, for example, chemical mechanical planarization or polishing (CMP), and/or grinding, may subsequently be performed to create a substantially planar top surface 312. As depicted by FIG. 17, the ILD layer 310 is formed such that the top surface 312 of the ILD layer 310 is located above the top surfaces of the top electrode 270P and dielectric encapsulation layer 290, respectively. This is to allow for the subsequent formation of an upper electrically conductive structure 320 (depicted in FIG. 18) within the ILD layer 310 and on top of the top electrode 270P.

As further depicted by FIG. 17, the ILD layer 310 is formed in the inter-pillar gaps that are laterally adjacent to the pillar structure of MTJ device 100, such that the ILD layer 310 laterally surrounds the sidewall surfaces of the dielectric encapsulation layer 290. In other words, the ILD layer 310 is formed in the gaps between MTJ device 100 and other adjacent MTJ devices (not depicted) formed at this stage in the semiconductor fabrication process. It should be appreciated that due to the low aspect ratio of the inter-pillar gaps at this stage in the semiconductor manufacturing process, the likelihood of voids being formed when filling the inter-pillar gaps is reduced, which ultimately results in a reduced risk of electrical shorts between the MTJ device 100 and other neighboring MTJ devices.

FIG. 18 illustrates a cross-sectional view of MTJ device 100 of FIG. 17 after performing subsequent processing steps, in accordance with at least one embodiment of the present invention. In assembly of MTJ device 100 of FIG. 18, an upper electrically conductive structure 320 is formed within the ILD layer 310 and on top of top electrode 270P. Collectively, the upper electrically conductive structure 320 and the ILD layer 310 are part of an interconnect level. It should be noted that one or more additional BEOL interconnect levels and/or MOL interconnect levels may be located above this interconnect level. These other levels are not shown for clarity.

The upper electrically conductive structure 320 may be formed within the ILD layer 310 using one or more conventional BEOL semiconductor manufacturing processes (e.g., a damascene process or a dual damascene process) as known by one of ordinary skill in the art, and as such, a more detailed description of such processes is not presented herein. The upper electrically conductive structure 320 may include a conductive material including, but not limited to, copper (Cu), aluminum (Al), ruthenium (Ru), rhodium (Rh), iridium (Ir), tantalum (Ta), tantalum nitride (TaN), titanium (Ti), titanium nitride (TiN), tungsten (W), molybdenum (Mo), or any combination thereof. In some embodiments, and as depicted in FIG. 18, the lower electrically conductive structure 120 and the upper electrically conductive structure 320 are formed from the same materials. However, in other embodiments (not shown), the lower electrically conductive structure 120 and the upper electrically conductive structure 320 may be formed from different materials.

In some embodiments, and as depicted in FIG. 18, a diffusion barrier liner 315 is formed along the bottom and sidewall surfaces of an opening (not depicted) formed within the ILD layer 310. The diffusion barrier liner 315 is composed of a diffusion barrier material (i.e., a material that serves as a barrier to prevent a conductive material used to form upper electrically conductive structure 320 from diffusing into the ILD layer 310). The diffusion barrier liner 315 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN), or combinations of barrier materials such as RuTaN, Ta/TaN, CoWP, NiMoP, or NiMoB which are suitable for the given application.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A magnetic tunnel junction device, comprising:
a bottom electrode;
a magnetic tunnel junction pillar formed above the bottom electrode, wherein the magnetic tunnel junction pillar includes:
a reference layer formed on top of the bottom electrode,
a dielectric layer formed on top of the reference layer,
a free layer formed within the dielectric layer, and partially within a recessed area of the reference layer, and
a tunnel barrier layer separating the reference layer from the free layer, wherein bottom and sidewall surfaces of the free layer are encased by the tunnel barrier layer; and
a top electrode formed above the magnetic tunnel junction pillar.

2. The magnetic tunnel junction device of claim 1, wherein a bottom surface of the free layer is located below a top surface of the reference layer.

3. The magnetic tunnel junction device of claim 1, wherein the tunnel barrier layer is conformally formed to completely cover the bottom and sidewall surfaces of the free layer.

4. The magnetic tunnel junction device of claim 1, wherein the reference layer is formed using a subtractive manufacturing process, and the free layer is formed using an additive manufacturing process.

5. The magnetic tunnel junction device of claim 1, further comprising a first dielectric encapsulation layer formed on sidewall surfaces of the bottom electrode and the reference layer.

6. The magnetic tunnel junction device of claim 5, further comprising a first interlayer dielectric layer formed within inter-pillar gaps located laterally adjacent to the first dielectric encapsulation layer, wherein the first interlayer dielectric layer laterally surrounds the first dielectric encapsulation layer formed on the sidewall surfaces of the bottom electrode and the reference layer.

7. The magnetic tunnel junction device of claim 5, wherein the first dielectric encapsulation layer and the first interlayer dielectric layer are formed from compositionally different dielectric materials.

8. The magnetic tunnel junction device of claim 1, further comprising a second dielectric encapsulation layer formed on sidewall surfaces of the tunnel barrier layer and the top electrode.

9. The magnetic tunnel junction device of claim 8, further comprising a second interlayer dielectric layer formed within inter-pillar gaps located laterally adjacent to the second dielectric encapsulation layer, wherein the second interlayer dielectric layer laterally surrounds the second dielectric encapsulation layer formed on the sidewall surfaces of the tunnel barrier layer and the top electrode.

10. The magnetic tunnel junction device of claim 9, wherein the second dielectric encapsulation layer and the second interlayer dielectric layer are formed from compositionally different dielectric materials.

11. The magnetic tunnel junction device of claim 1, wherein the tunnel barrier layer is further formed between the dielectric layer and the top electrode.

12. The magnetic tunnel junction device of claim 11, wherein a top surface of the free layer is substantially coplanar with a top surface of the tunnel barrier layer formed between the dielectric layer and the top electrode.

13. The magnetic tunnel junction device of claim 12, wherein the top electrode is formed on the top surface of the free layer and the top surface of tunnel barrier layer.

14. A method of forming a magnetic tunnel junction device, comprising:
forming a bottom electrode;
forming a magnetic tunnel junction pillar above the bottom electrode, wherein forming the magnetic tunnel junction pillar includes:
forming a reference layer on top of the bottom electrode,
forming a dielectric layer above the reference layer,
forming an opening that extends completely through the dielectric layer and partially through the reference layer,
conformally depositing a tunnel barrier material to form a tunnel barrier layer, wherein the tunnel barrier layer is formed on bottom and sidewall surfaces of the opening, such that the tunnel barrier layer lines the opening, and
forming a free layer within the opening lined by the tunnel barrier layer; and
forming a top electrode above the free layer.

15. The method of claim 14, wherein the tunnel barrier layer is conformally formed to completely cover the bottom and sidewall surfaces of the free layer.

16. The method of claim 14, wherein the tunnel barrier layer is further formed on a top surface of the dielectric layer.

17. The method of claim 14, wherein the reference layer is formed using a subtractive manufacturing process, and the free layer is formed using an additive manufacturing process.

18. The method of claim 14, wherein forming the bottom electrode and the reference layer on top of the bottom electrode includes:
forming a material stack including a bottom electrode layer and a reference layer on top of the bottom electrode layer;
forming a patterned hard mask on top of the reference layer; and
etching, using the patterned hard mask, the physically exposed portions of the reference layer and the bottom electrode layer.

19. The method of claim 14, further comprising:
forming a first dielectric encapsulation layer on sidewall surfaces of the bottom electrode and reference layer; and
forming a first interlayer dielectric layer to fill inter-pillar gaps located laterally adjacent to the first dielectric encapsulation layer, wherein the first interlayer dielectric layer surrounds the first dielectric encapsulation layer formed on the sidewall surfaces of the bottom electrode and the reference layer.

20. The method of claim 1, further comprising:
forming a second dielectric encapsulation layer on sidewall surfaces of the tunnel barrier layer and the top electrode; and
forming a second interlayer dielectric layer to fill inter-pillar gaps located laterally adjacent to the second dielectric encapsulation layer, wherein the second interlayer dielectric layer surrounds the second dielectric encapsulation layer formed on the sidewall surfaces of the tunnel barrier layer and the free layer.
